(19) United States
(12) Patent Application Publication
(10) Pub. No.: US 2026/0185946 A1
(43) Pub. Date: Jul. 2, 2026

(54) SUBSTRATE PROCESSING METHOD AND APPARATUS

(71) Applicant: SEMES CO., LTD., Cheonan-si (KR)

(72) Inventor: Sung Pil KIM, Hwaseong-si (KR)

(73) Assignee: SEMES CO., LTD., Cheonan-si (KR)

(21) Appl. No.: 19/434,251

(22) Filed: Dec. 29, 2025

(30) Foreign Application Priority Data
Dec. 30, 2024 (KR) 10-2024-0199958

(51) Int. Cl. G01N 21/94; B08B 3/04; B08B 9/00; B08B 13/00; B08B 15/02; G01N 21/33; G06T 7/00; H10P 72/00

(52) U.S. Cl. CPC G01N 21/94; B08B 3/04; B08B 9/00; B08B 13/00; B08B 15/02; G01N 21/33; G06T 7/001; G06T 2207/30121; G06T 2207/30148; H10P 72/0404

(57) ABSTRACT

Provided is a substrate processing method and apparatus. The substrate processing method includes: a substrate processing operation of discharging a liquid to a substrate loaded into an inner space of a liquid treating chamber to liquid-treat the substrate; after the substrate processing operation, a chamber cleaning operation of unloading the substrate from the inner space of the liquid treating chamber and cleaning the liquid treating chamber; and an inspection operation of inspecting a degree of contamination of the liquid treating chamber after the chamber cleaning operation, in which the inspection operation includes acquiring an image by photographing the inner space with a camera in a state where first light of a wavelength band in an ultraviolet ray region to the inner space of the liquid treating chamber, and inspecting the degree of contamination of the liquid treating chamber based on the image.

### CROSS-REFERENCE TO RELATED APPLICATION

This application claims priority to and the benefit of Korean Patent Application No. 10-2024-0199958 filed in the Korean Intellectual Property Office on Dec. 30, 2024, the entire contents of which are incorporated herein by reference.

### TECHNICAL FIELD

The present invention relates to a method and an apparatus for processing a substrate, and more particularly, to a method and an apparatus for processing a substrate by supplying a treatment liquid to a substrate.

### BACKGROUND ART

In order to manufacture a semiconductor device or a liquid crystal display, various processes, such as photolithography, ashing, etching, ion implantation, thin film deposition, and cleaning, for a substrate may be performed. Among them, the cleaning process is a process for removing particles remaining on the substrate, and is performed before and after each process.

This cleaning process is applied differently depending on the surface properties of the substrate. In particular, in the case of hydrophobizing the surface of the substrate or washing the hydrophobized surface, a chemical treatment operation and a rinse treatment operation are performed. The substrate may be supplied with a chemical while being rotated, and a rinse liquid, such as isopropyl alcohol, may be supplied thereafter.

When the cleaning process is performed, particles are generated by a chemical and rinse liquid, and by abrasion of components included in a liquid treating chamber. When particles accumulate more than a certain amount, it affects the overall cleaning process. Therefore, after performing the cleaning process, maintenance is performed to remove particles or a process of cleaning the inside of the liquid treating chamber is performed. However, even after the maintenance or cleaning process, fine particles may remain in the inner wall of the chamber or in the components in the chamber.

### SUMMARY OF THE INVENTION

The present invention has been made in an effort to provide a substrate processing method and apparatus capable of detecting whether cleaning has been performed normally after cleaning a liquid treating chamber.

The present invention has also been made in an effort to provide a substrate processing method and apparatus capable of easily detecting particles remaining in an inner space of a liquid treating chamber.

The objectives of the present disclosure are not limited thereto and other objectives not stated herein may be clearly understood by those skilled in the art from the following description.

An exemplary embodiment of the present disclosure, a method of processing a substrate, the method comprising: a substrate processing operation of discharging a liquid to a substrate loaded into an inner space of a liquid treating chamber to liquid-treat the substrate; after the substrate processing operation, a chamber cleaning operation of unloading the substrate from the inner space of the liquid treating chamber and cleaning the liquid treating chamber; and an inspection operation of inspecting a degree of contamination of the liquid treating chamber after the chamber cleaning operation, wherein the inspection operation may include acquiring an image by photographing the inner space with a camera in a state where first light of a wavelength band in an ultraviolet ray region to the inner space of the liquid treating chamber, and inspecting the degree of contamination of the liquid treating chamber based on the image.

According to the exemplary embodiment of the present invention, wherein in the inspection operation, the degree of contamination of the liquid treating chamber may be performed by detecting the amount of particles remaining in the liquid treating chamber from the image.

According to the exemplary embodiment of the present invention, wherein the degree of contamination of the liquid treating chamber may be a degree of contamination of an inner wall of the liquid treating chamber or a degree of contamination of a component provided to the liquid treating chamber.

According to the exemplary embodiment of the present invention, further may comprising: an additional cleaning operation of secondarily cleaning the liquid treating chamber when it is determined that the degree of contamination is equal to or greater than a preset value in the inspection operation.

According to the exemplary embodiment of the present invention, wherein in the chamber cleaning operation, the liquid treating chamber is cleaned with a cleaning liquid in a state where descending airflow is supplied to the inner space at a first supply amount per unit time, in the additional cleaning operation, the liquid treating chamber is cleaned with the cleaning liquid in a state where descending airflow is supplied to the inner space at a second supply amount per unit time, and the second supply amount may be greater than the first supply amount.

According to the exemplary embodiment of the present invention, wherein in the additional cleaning operation, the second supply amount may be determined based on the amount of particles detected in the inspection operation.

According to the exemplary embodiment of the present invention, wherein an exhaust pressure of the inner space in the additional cleaning operation is greater than an exhaust pressure of the inner space in the chamber cleaning operation, and a pressure of the inner space in the chamber cleaning operation and a pressure of the inner space in the additional cleaning operation may be the same.

According to the exemplary embodiment of the present invention, wherein in the substrate processing operation or the chamber cleaning operation, the inner space may be photographed by the camera in a state where second light of a different wavelength band from the first light is emitted to the inner space.

According to the exemplary embodiment of the present invention, wherein in the substrate processing operation or the chamber cleaning operation, only the second light between the first light and the second light is emitted, and in the inspection operation, only the first light between the first light and the second light may be emitted.

According to the exemplary embodiment of the present invention, wherein the second light may be light of a wavelength band of a visible light region.

An exemplary embodiment of the present disclosure, an apparatus for processing a substrate, the apparatus comprising: a housing for forming an inner space; a cup disposed in the inner space and providing a treatment space for processing a substrate; a support unit for supporting a substrate in the treatment space; a liquid supply unit for supplying a liquid to the substrate supported by the support unit; an airflow supply unit installed on an upper surface of the housing and supplying airflow to the inner space; an exhaust unit installed in the housing and exhausting atmosphere of the inner space; a first light source for emitting first light to the inner space; and a camera for photographing the inner space, wherein the first light may be light of a wavelength band of a ultraviolet ray region.

According to the exemplary embodiment of the present invention, further may comprising: a second light source for emitting second light of a wavelength band different from the first light to the inner space.

According to the exemplary embodiment of the present invention, wherein the second light may be light of a wavelength band of a visible light region.

According to the exemplary embodiment of the present invention, wherein the first light source may be provided at an end of the airflow supply unit or a region adjacent to the airflow supply unit to surround the airflow supply unit.

According to the exemplary embodiment of the present invention, wherein the camera may be an ultraviolet camera.

According to the exemplary embodiment of the present invention, further comprising: a control unit for controlling the liquid supply unit, the first light source, and the camera, wherein the control unit may controls the liquid supply unit, the first light source, and the camera to sequentially perform: a substrate processing operation of discharging a liquid to a substrate loaded into an inner space to liquid-treat the substrate; a chamber cleaning operation of unloading the substrate from the inner space and cleaning the inner space, after the substrate processing operation; and an inspection operation of inspecting a degree of contamination of the inner space based on an image acquired by the camera in a state where the first light is emitted, after the chamber cleaning operation.

According to the exemplary embodiment of the present invention, wherein the control unit determines whether the degree of contamination of the inner space is equal to or greater than a preset value based on the image, and may controls the liquid supply unit, the airflow supply unit, and the exhaust unit to additionally perform an additional cleaning operation of secondarily cleaning the inner space when the degree of contamination is equal to or greater than the preset value.

An exemplary embodiment of the present disclosure, a method of processing a substrate, the method comprising: a substrate processing operation of discharging a liquid to a substrate loaded into an inner space of a liquid treating chamber to liquid-treat the substrate; a chamber cleaning operation of unloading the substrate from the inner space of the liquid treating chamber and cleaning the liquid treating chamber, after the substrate processing operation; and an inspection operation of inspecting a degree of contamination of the liquid treating chamber, after the chamber cleaning operation, wherein the inspection operation includes acquiring an image by photographing the inner space with a camera in a state where first light of a wavelength band of an ultraviolet ray region to the inner space of the liquid treating chamber, and inspecting a degree of contamination of the liquid treating chamber based on the image, in the substrate processing operation or the chamber cleaning operation, the inner space is photographed by the camera in a state where second light of a different wavelength band from the first light is emitted to the inner space, in the substrate processing operation or the chamber cleaning operation, only the second light between the first light and the second light is emitted, in the inspection operation, only the first light between the first light and the second light is emitted, and the wavelength band of the second light may be a wavelength band of a visible light region.

According to the exemplary embodiment of the present invention, further comprising: an additional cleaning operation of secondarily cleaning the liquid treating chamber when it is determined that the degree of contamination is equal to or greater than a preset value in the inspection operation, wherein in the chamber cleaning operation, the liquid treating chamber is cleaned with a cleaning liquid in a state where descending airflow is supplied to the inner space at a first supply amount per unit time, in the additional cleaning operation, the liquid treating chamber is cleaned with the cleaning liquid in a state where descending airflow is supplied to the inner space at a second supply amount per unit time, and the second supply amount may be greater than the first supply amount.

According to the exemplary embodiment of the present invention, wherein in the additional cleaning operation, the second supply amount is determined based on the amount of particles detected in the inspection operation, an exhaust pressure of the inner space is greater than an exhaust pressure of the inner space in the chamber cleaning operation, and a pressure of the inner space in the chamber cleaning operation and a pressure of the inner space in the additional cleaning operation may be the same.

According to the present invention, it is possible to detect whether cleaning has been carried out normally after cleaning a liquid treating chamber.

According to the present invention, it is possible to easily detect particles remaining in an inner space of a liquid treating chamber.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a top plan view schematically illustrating a substrate processing apparatus according to an exemplary embodiment of the present invention.

FIG. 2 is a top plan view of a process chamber of the substrate processing apparatus of FIG. 1, viewed from the front.

FIG. 3 is a top plan view of a liquid treating chamber of FIG. 2 viewed from above.

FIG. 4 is a diagram of an airflow supply unit according to an exemplary embodiment of the present invention as viewed from below.

FIGS. 5 to 6 are flowcharts of a substrate processing method according to an exemplary embodiment of the present invention.

FIGS. 7 to 8 are conceptual diagrams for describing an image of an inner space of the liquid treating chamber when a second light is emitted thereto.

FIGS. 9 to 10 are conceptual views for describing an image of the inner space of the liquid treating chamber when a first light is emitted thereto.

FIG. 11 is a conceptual view for describing a light emitting unit according to an exemplary embodiment of the present invention.

FIG. 12 is a conceptual view for describing the light emitting unit according to the exemplary embodiment of the present invention.

FIG. 13 is a conceptual view for describing the light emitting unit according to the exemplary embodiment of the present invention.

### DETAILED DESCRIPTION

Hereinafter, exemplary embodiments of the present invention will be described in more detail with reference to the accompanying drawings. The exemplary embodiments of the present invention may be modified in various forms, and the scope of the present invention should not be construed as being limited to the exemplary embodiments described below. The present exemplary embodiment is provided to more completely describe the present invention to a person having average knowledge in the art. Therefore, the shapes of components in the drawings are exaggerated to emphasize a clearer description.

In the present exemplary embodiment, the present invention will be described based on a process of liquid-treating a substrate by supplying a liquid, such as a cleaning liquid, onto the substrate as an example. However, the present exemplary embodiment is not limited to the cleaning process, but is applicable to various processes of treating the substrate using a treatment liquid, such as an etching process, an ashing process, and a developing process.

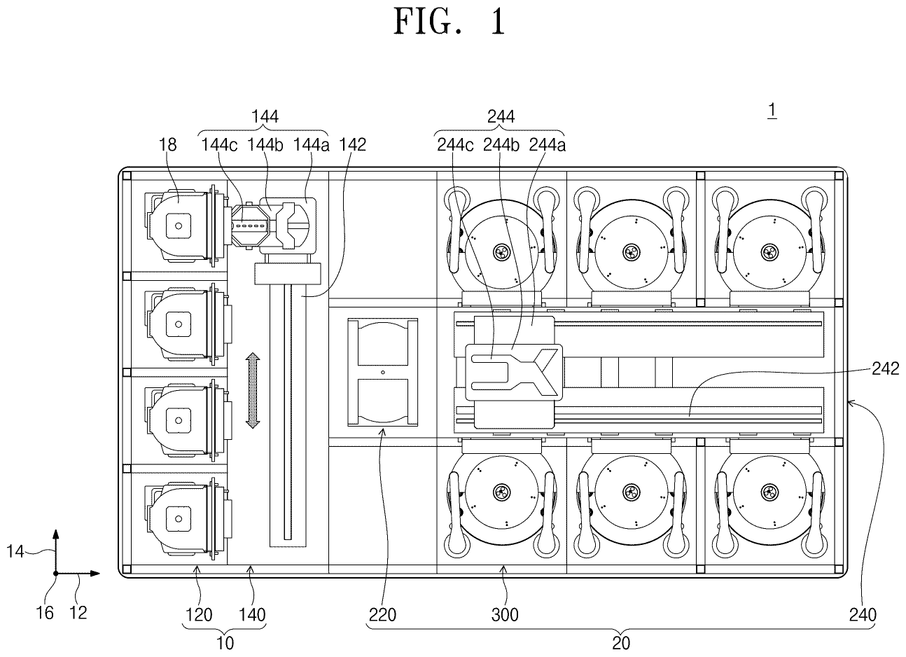

FIG. 1 is a plan view schematically illustrating a substrate processing apparatus according to an exemplary embodiment of the present invention.

Referring to FIG. 1, a substrate processing apparatus 1 includes an index module 10 and a process processing module 20. The index module 10 includes a load port 120 and a transfer frame 140. The load port 120, the transfer frame 140, and the process processing module 20 are sequentially arranged in a line. Hereinafter, a direction in which the load port 120, the transfer frame 140, and the process processing module 20 are arranged is referred to as a first direction 12, a direction perpendicular to the first direction 12 when viewed from above is referred to as a second direction 14, and a direction perpendicular to a plane including the first direction 12 and the second direction 14 is referred to as a third direction 16.

A container 130 in which the substrate W is accommodated is seated on the load port 120. A plurality of load ports 120 is provided, and they are arranged in a line along the second direction 14. The number of load ports 120 may increase or decrease depending on the process efficiency, the foot print condition, and the like of the process processing module 20. A plurality of slots (not illustrated) for accommodating the substrates W in a state in which the substrates are horizontally arranged with respect to the ground is formed in the container 130. A Front Open Integrated Pod (FOUP) is used as the container 130.

The process processing module 20 includes a buffer unit 220, a transfer chamber 240, and a process chamber 300. A longitudinal direction of the transfer chamber 240 is disposed parallel to the first direction 12. Process chambers 300 are disposed on both sides of the transfer chamber 240, respectively. The process chambers 300 are provided to be symmetrical with respect to the transfer chamber 240 on one side and the other side of the transfer chamber 240. A plurality of process chambers 300 is provided on one side of the transfer chamber 240. Some of the process chambers 300 are disposed along the longitudinal direction of the transfer chamber 240. In addition, some of the process chambers 300 are arranged to be stacked on each other. That is, the process chambers 260 are disposed on one side of the transfer chamber 240 in an arrangement of A×B. Herein, A is the number of process chambers 300 provided in a row along the first direction 12, and B is the number of process chambers 300 provided in a row along the third direction 16. When four or six process chambers 300 are provided on one side of the transfer chamber 240, the process chambers 300 are disposed in a 2×2 or 3×2 arrangement. The number of process chambers 300 may increase or decrease. Unlike the above description, the process chamber 300 is provided only to one side of the transfer chamber 240. In addition, the process chambers 300 are provided as a single layer on one side and opposite sides of the transfer chamber 240.

The buffer unit 220 is disposed between the transfer frame 140 and the transfer chamber 240. The buffer unit 220 provides a space in which the substrate W stays before the substrate W is transferred between the transfer chamber 240 and the transfer frame 140. A slot (not illustrated) in which the substrate W is placed is provided in the buffer unit 220. A plurality of slots (not illustrated) is provided to be spaced apart from each other along a third direction 16. The buffer unit 220 opens the surface facing the transfer frame 140 and the surface facing the transfer chamber 240.

The transfer frame 140 transfers the substrate W between the container 130 seated on the load port 120 and the buffer unit 220. An index rail 142 and an index robot 144 are provided in the transfer frame 140. The longitudinal direction of the index rail 142 is provided in parallel to the second direction 14. The index robot 144 is installed on the index rail 142 and moves linearly in the second direction 14 along the index rail 142. The index robot 144 has a base 144a, a body 144b, and an index arm 144c. The base 144a is installed to be movable along the index rail 142. The body 144b is coupled to the base 144a. The body 144b is provided on the base 144a to be movable along the third direction 16. In addition, the body 144b is provided to be rotatable on the base 144a. The index arm 144c is coupled to the body 144b and is provided to be able to move forward and backward with respect to the body 144b. A plurality of index arms 144c is provided to be individually driven. The index arms 144c are disposed to be stacked while being spaced apart from each other along the third direction 16. Some of the index arms 144c are used to transfer the substrate W from the process processing module 20 to the container 130, and another some thereof is used to transfer the substrate W from the container 130 to the process processing module 20. This prevents particles generated from the substrate W before the process processing in the process in which the index robot 144 loads and unloads the substrate W from adhering to the substrate W after the process processing.

The transfer chamber 240 transfers the substrate W between the buffer unit 220 and the process processing chamber 300 and between the process processing chambers 300. A guide rail 242 and a main robot 244 are provided in the transfer chamber 240. The guide rail 242 is arranged such that its longitudinal direction is parallel to the first direction 12. The main robot 244 is installed on the guide rail 242, and moves linearly along the first direction 12 on the guide rail 242. The main robot 244 includes a base 244a, a body 244b, and a main arm 244c. The base 244a is installed to be movable along the guide rail 242. The body 244b is coupled to the base 244a. The body 244b is provided on the base 244a to be movable along the third direction 16. Furthermore, the body 244b is provided on the base 244a to be rotatable on the base 244a. The main arm 244c is coupled to the body 244b, which is provided to be movable forward and backward with respect to the body 244b. A plurality of index arms 244c is provided to be individually driven. The main arms 244c are arranged to be stacked while being spaced apart from each other along the third direction 16.

The process chamber 300 may be a liquid treating chamber for performing a liquid treatment process by supplying a liquid to the substrate W. For example, the liquid treating process may be a cleaning process for cleaning a substrate with a cleaning liquid. Chemical treatment, rinsing treatment, and drying treatment are all performed on the substrate in the process chamber. Optionally, a drying chamber for drying the substrate may be provided separately from the liquid treating chamber.

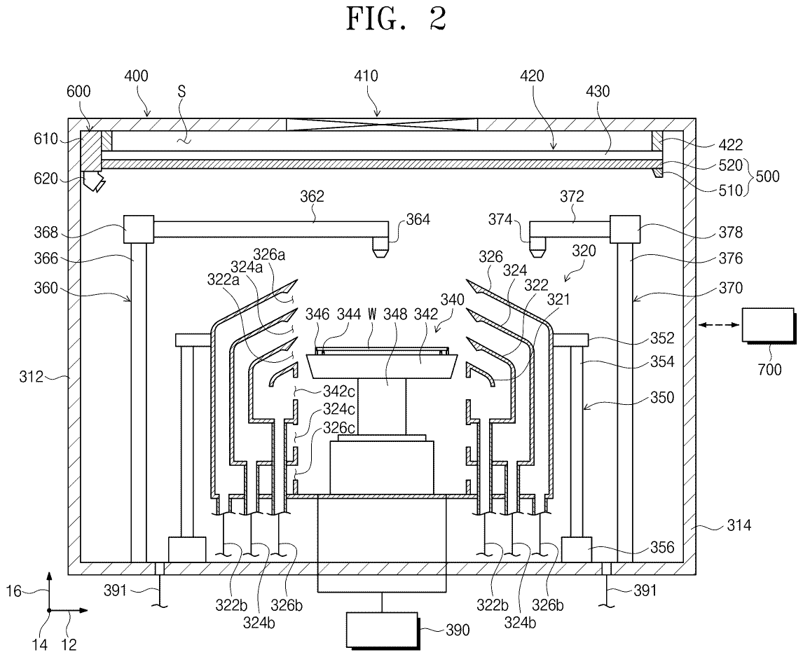

FIG. 2 is a cross-sectional view schematically illustrating the process chamber of FIG. 1 according to the exemplary embodiment.

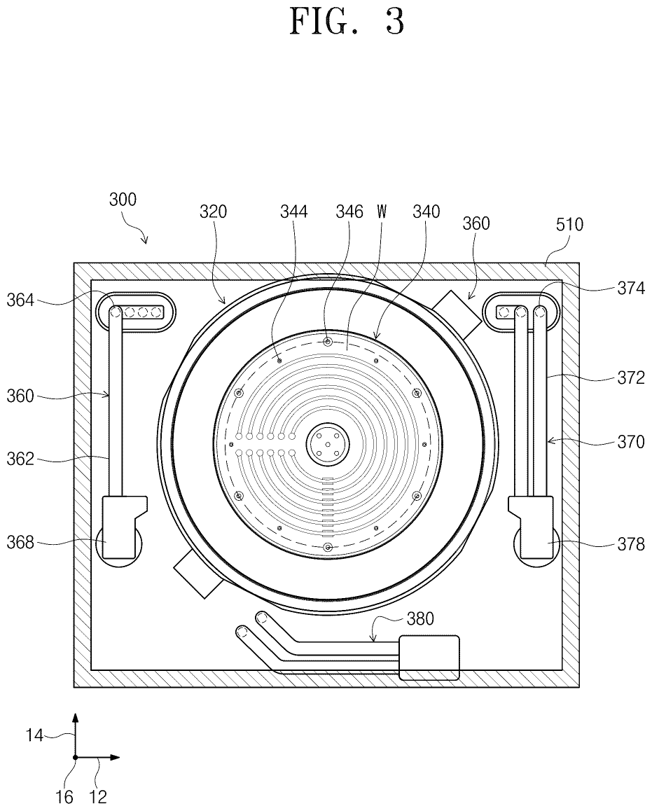

Referring to FIG. 3, the process chamber 300 includes a housing 310, a cup 320, a support unit 340, a lifting unit 350, a first liquid supply unit 360, a second liquid supply unit 370, a third liquid supply unit 380, an exhaust unit 390, an airflow supply unit 400, a light emitting unit 500, a photographing unit 600, and a control unit 700.

The housing 310 forms an inner space. The housing 310 has an upper wall 311, side walls 312, 313, and a bottom wall 314, and the inner space is a space defined by the side walls 312 and 313 and the bottom wall 314. According to an example, the housing generally has a rectangular parallelepiped shape, and the side walls of the housing have a first side wall 312 and a second side wall 313. The first side wall 312 is positioned to face the second side wall 313.

The cup 320 is located in the inner space. The housing 320 provides a treatment space for processing the substrate W. The cup 320 includes a guide wall 321, an inner recovery container 322, a middle recovery container 324, and an outer recovery container 326. Each of the recovery containers 322, 324, and 326 separates and recovers different treatment liquids from the treatment liquids used in the process. The guide wall 321 is provided in an annular ring shape surrounding the support unit 340, and the inner recovery container 322 is provided in an annular ring shape surrounding the guide wall 321. The middle recovery container 324 is provided in an annular ring shape surrounding the inner recovery container 322, and the outer recovery container 326 is provided in an annular ring shape surrounding the middle recovery container 324. The space 322a between the inner recovery container 322 and the guide wall 321 functions as a first inlet through which the treatment liquid is introduced. The space 324a between the inner recovery container 322 and the middle recovery container 324 functions as a second inlet through which the treatment liquid is introduced. The space 326a between the middle recovery container 324 and the outer recovery container 326 functions as a third inlet through which the treatment liquid is introduced. Further, the space 322c between a lower end of the guide wall 321 and the inner recovery container 322 functions as a first outlet through which fume and airflow generated from the treatment liquid are discharged. The space 324c between a lower end of the inner recovery container 322 and the middle recovery container 324 functions as a second outlet through which fume and airflow generated from the treatment liquid are discharged. The space 326c between a lower end of the middle recovery container 324 and the outer recovery container 326 functions as a third outlet through which fume and airflow generated from the treatment liquid are discharged. Different types of treatment liquid are introduced into the recovery container, respectively. The recovery containers 322, 324, and 326 are connected with recovery lines 322b, 324b, and 326b extending vertically in a direction below the bottom surface thereof, respectively. The recovery lines 322b, 324b, and 326b discharge the treatment liquid, fume, and airflow introduced through the recovery containers 322, 324, and 326, respectively. The discharged treatment liquid is reused through an external treatment liquid regeneration system (not illustrated).

The support unit 340 supports the substrate W and rotates the substrate W during the process. The support unit 340 includes a spin chuck 342, a support pin 344, a chuck pin 346, a support shaft 348, and a driving unit (not illustrated). The spin chuck 342 has an upper surface that is provided in a generally circular shape when viewed from the top. The support shaft 348 is fixedly coupled to a bottom surface of the spin chuck 342, and the support shaft 348 is rotatably provided by a driving unit.

A plurality of support pins 344 is provided. The support pins 344 are disposed on the edge portion of the upper surface of the spin chuck 342 to be spaced apart from each other by a predetermined interval and protrude upward from the spin chuck 342. The support pin 344 supports the rear edge of the substrate W so that the substrate W is spaced apart from the upper surface of the spin chuck 342 by a predetermined distance.

A plurality of chuck pins 346 is provided. The chuck pin 346 is disposed to be farther from the center of the spin chuck 342 than the support pin 344. The chuck pin 346 is provided to protrude upward from the spin chuck 342. The chuck pin 346 supports a side portion of the substrate W so as not to be separated from a regular position in a lateral direction when the substrate W is rotated. The chuck pin 346 is provided to be able to move linearly between a standby position and a support position along a radial direction of the spin chuck 342. The standby position is a position farther from the center of the spin chuck 342 than the support position. When the substrate W is loaded on or unloaded from the spin chuck 340, the chuck pin 346 is located at the standby position, and when the process is performed on the substrate W, the chuck pin 346 is located at the support position. At the support position, the chuck pin 346 is in contact with the side portion of the substrate W.

The lifting unit 350 linearly moves the cup 320 in the up and down direction. As the cup 320 is moved up and down, a relative height of the cup 320 with respect to the spin head of the support unit 340 is changed. The lifting unit 350 includes a bracket 352, a moving shaft 354, and a driver 356. The bracket 352 is fixedly installed on the outer wall of the cup 320, and the moving shaft 352 that is moved in the up and down direction by the driver 356 is fixedly coupled to the bracket 354. When the substrate W is placed on the spin head of the support unit 340 or lifted from the spin head of the support unit 340, the cup 320 is lowered so that the spin head of the support unit 340 protrudes upward from the cup 320. Also, when the process is performed, the height of the cup 320 is adjusted so that the treatment liquid may be introduced into a preset recovery container according to the type of treatment liquid supplied to the substrate W. Selectively, the lifting unit 350 may move the spin head of the support unit 340 in the vertical direction.

The first liquid supply unit 360, the second liquid supply unit 370, and the third liquid supply unit 377 supply the liquid onto the substrate W. The liquid includes a treatment liquid and a cleaning liquid. The treatment liquid includes a chemical and rinse liquid. The cleaning liquid includes a chemical and an organic solvent. The chemical includes nitric acid, phosphoric acid or sulfuric acid. The rinse liquid includes water. The organic solvent includes alcohol, such as isopropyl alcohol. For example, the first liquid supply unit 360 may supply a chemical, the second liquid supply unit 370 may supply a rinse liquid, and the third liquid supply unit 380 may supply an organic solvent.

The first liquid supply unit 360 includes a first support shaft 366, a first arm 362, a first driver 368, and a first nozzle 364. The first support shaft 366 is disposed at one side of the cup 320. The first support shaft 366 has a rod shape of which a longitudinal direction thereof faces a third direction 16. The first support shaft 366 is provided to be rotatable by the first driver 368. The first arm 362 is coupled to an upper end of the first support shaft 366. The first arm 362 vertically extends from the first support shaft 366. The first nozzle 364 is fixedly coupled to an end of the first arm 362. As the first support shaft 366 is rotated, the first nozzle 364 is capable of swing and moving together with the first arm 362. The first nozzle 364 is swing-moved and moved to a process position and a standby position. Here, the process position is a position where the first nozzle 364 is opposite to the substrate W supported by the support unit 340, and the standby position is a position where the first nozzle 364 is out of the process position.

The second liquid supply unit 370 and the third liquid supply unit 380 are similar to the first liquid supply unit 360 described above, and a detailed description thereof will be omitted.

The exhaust unit 390 exhausts the atmosphere generated in the treatment space. The atmosphere is composed of fumes and gas, and the fume includes particles. The exhaust unit 390 exhausts fumes and gas generated when a substrate is liquid-treated. The exhaust unit 390 is coupled to the bottom surface of the cup 320.

The exhaust duct 391 exhausts the atmosphere of the inner space of the housing 310. The exhaust duct 391 exhausts fume and gas scattered in the treatment space when a substrate is liquid-treated. The exhaust duct 391 is coupled to the bottom wall of the housing 310.

While the substrate W is liquid-treated, the atmosphere is exhausted only through the exhaust unit 390 between the exhaust unit 390 and the exhaust duct 391. Optionally, while the substrate is liquid-treated, the atmosphere is simultaneously exhausted through the exhaust unit 390 and the exhaust duct 391. In this case, when the substrate W is liquid-treated, the exhaust duct 391 sets an exhaust pressure to be lower than an exhaust pressure of the exhaust unit 390, and thus exhausts less than the exhaust unit 390. For this reason, the atmosphere generated in the treatment space is prevented from flowing back to the outside of the treatment space.

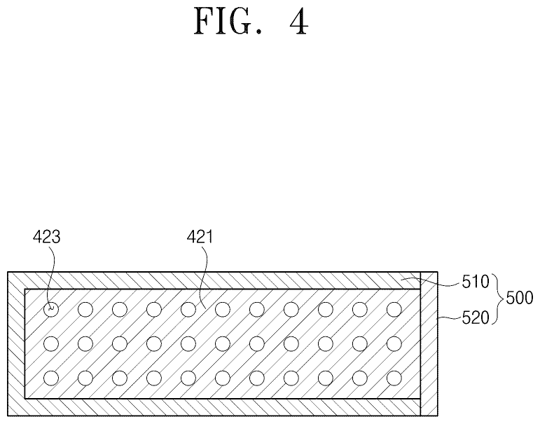

FIG. 4 is a diagram of the airflow supply unit according to the exemplary embodiment of the present invention as viewed from below.

In addition to FIGS. 2 to 3, the airflow supply unit 400 and the light emitting unit 500 will be described with reference to FIG. 4.

The airflow supply unit 400 provides descending airflow to the inner space of the housing 310. The airflow supply unit 400 is installed in an upper portion of the inner space of the housing 310. The airflow supply unit 400 includes a fan filter 410 and a perforated plate 420.

The fan filter 410 is installed on the upper wall 311 of the housing 310. The fan filter 410 sucks outside gas and filters the sucked gas.

The perforated plate 420 is installed in the upper portion of the housing 310. The perforated plate 420 includes a lower wall 421 and a side wall 422. The lower wall 421 and the side wall 422 form an airflow introduction space S with the upper wall 311 of the housing 310. The lower wall 421 and the side wall 422 are formed with outlet holes 423 respectively.

The external gas is sucked and filtered through the fan filter 410, introduced into the airflow introduction space S, and introduced into the inner space through the outlet hole 423.

The light emitting unit 500 is installed in the airflow supply unit 400. In one exemplary embodiment, the light emitting unit 500 is provided at an end of the perforated plate 420. Alternatively, the light emitting unit 500 may be provided in a region adjacent to the perforated plate 420.

The light emitting unit 500 includes a first light source 510 and a second light source 520. The first light source 510 is installed under the airflow supply unit 400. When viewed from above, the first light source 510 is provided in a quadrangular ring shape surrounding the perforated plate 420. The second light source 520 is installed under the first light source 510. When viewed from the front, the second light source 520 is provided in a trapezoidal shape. When viewed from below, the second light source 520 overlaps one of the four sides of the first light source 510.

The first light source 510 is a light source for emitting first light, and the second light source 520 is a light source for emitting second light. The first light and the second light are light having different wavelength bands. The wavelength band of the first light is the wavelength band of the ultraviolet ray region, and the wavelength band of the second light is the wavelength band of the visible light region. For example, the wavelength band of the first light may be 315 nm to 400 nm, which is the wavelength band of ultraviolet A (UVA).

The photographing unit 600 is installed on the upper wall 311 of the housing 310. The photographing unit 600 includes a frame 610 and a camera 620. The frame 610 is installed on one side of the upper wall 311 of the housing 310. Although the one side wall of the frame 610 is in contact with the first side wall 312 of the housing 310, unlike this, opposite side walls of the frame 610 may be in contact with or be spaced apart from both the first side wall 312 of the housing 310 and the side wall 422 of the airflow supply unit 400.

The camera 620 is installed on a lower wall of the frame 610. The camera 620 photographs the inner space. Although it is illustrated that one camera 620 photographs the inner space irradiated with the first light and the inner space irradiated with the second light, unlike this, two cameras 620 may be provided in the photographing unit 600 to photograph the inner space irradiated with the first light and the inner space irradiated with the second light. In this case, one of the two cameras 620 is a visible light camera photographing the wavelength band of the visible light region, and the other is an ultraviolet camera photographing the wavelength band of the ultraviolet ray region.

The control unit 700 controls the cup 320, the support unit 340, the lifting unit 350, the first liquid supply unit 360, the second liquid supply unit 370, the third liquid supply unit 380, the exhaust unit 390, the airflow supply unit 400, the light emitting unit 500, and the photographing unit 600. The control unit 700 may control the cup 320, the support unit 340, the lifting unit 350, the first liquid supply unit 360, the second liquid supply unit 370, the third liquid supply unit 380, the exhaust unit 390, the airflow supply unit 400, the light emitting unit 500, and the photographing unit 600 so that a substrate processing method is performed as follows.

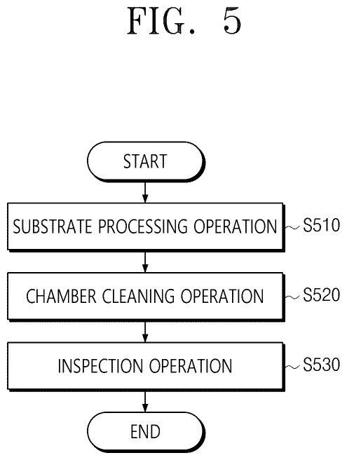

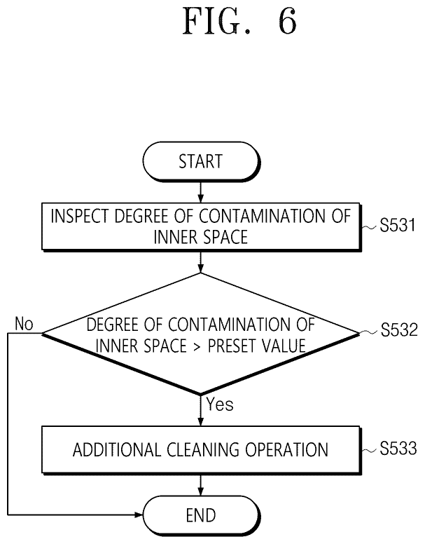

FIGS. 5 to 6 are flowcharts of a substrate processing method according to an exemplary embodiment of the present invention.

Referring to FIG. 5, a substrate processing method according to an exemplary embodiment of the present invention includes a substrate processing operation S510, a chamber cleaning operation S520, and an inspection operation S530.

First, a substrate processing operation is performed (S510). In the substrate processing operation, the substrate W is placed on the support spin chuck 342. The spin chuck 342 on which the substrate W is placed rotates, and the first liquid supply unit 360 and the second liquid supply unit 370 supply a chemical and a rinse liquid onto the substrate W, respectively.

In this case, the second light is emitted to the inner space, and the camera 620 photographs the inner space irradiated with the second light to acquire an image. The control unit 700 may monitor the processing state of the substrate W based on the image.

Thereafter, the substrate W is unloaded from the inner space of the liquid treating chamber 300, and a chamber cleaning operation is performed (S520). In the cleaning operation, the spin chuck 342 is rotated, and the first liquid supply unit 360 and the third supply unit 380 supply a chemical and an organic solvent to the spin chuck 342, respectively. Optionally, a cleaning jig is placed on the spin chuck 342, and the first liquid supply unit 360 and the third supply unit 380 may supply a chemical and an organic solvent onto the cleaning jig, respectively. In this case, the cleaning liquid is scattered from the spin chuck 342 by centrifugal force, and the components disposed on the inner wall of the liquid treating chamber 300, the inner wall of the cup 320, and the inner space are cleaned.

During the cleaning, the relative heights of the spin chuck 342 and the cup 320 are changed, the descending airflow is supplied to the inner space by the airflow supply unit 400, and the atmosphere of the inner space is exhausted by the exhaust unit 390. The supply amount per unit time of the descending airflow may be a first supply amount, the exhaust pressure per unit time of the exhaust unit 390 may be a first exhaust pressure, and the atmosphere of the inner space may be formed by the treatment liquid supplied in operation S510, particles generated during the processing of the substrate W, the cleaning liquid supplied in operation S520, and the descending airflow. In the chamber cleaning operation, the second light may be selectively emitted to the inner space.

When the chamber cleaning operation is completed, the inspection operation S530 is performed.

Referring to FIG. 6, in the inspection operation, the degree of contamination of the inner space is inspected (S531). The degree of contamination may be the degree of contamination of the inner wall of the liquid treating chamber 300 or the degree of contamination of components provided to the liquid treating chamber 300, and may be proportional to the amount of particles remaining in the inner space after the cleaning operation of S520 is performed.

When the degree of contamination of the inner space is inspected, the emission of the second light to the inner space is stopped, and the first light is emitted. The camera 620 acquires an image of the inner space by photographing the inner space irradiated with the first light.

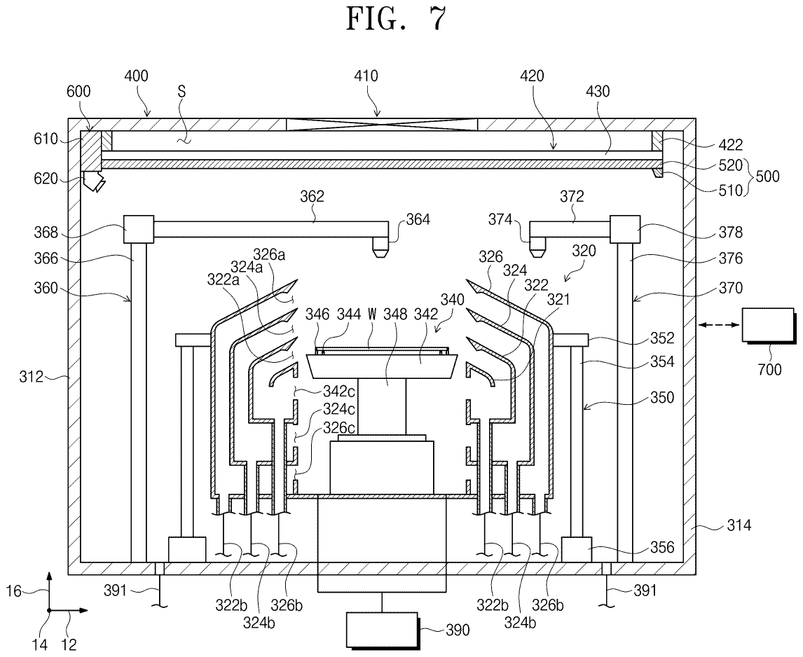

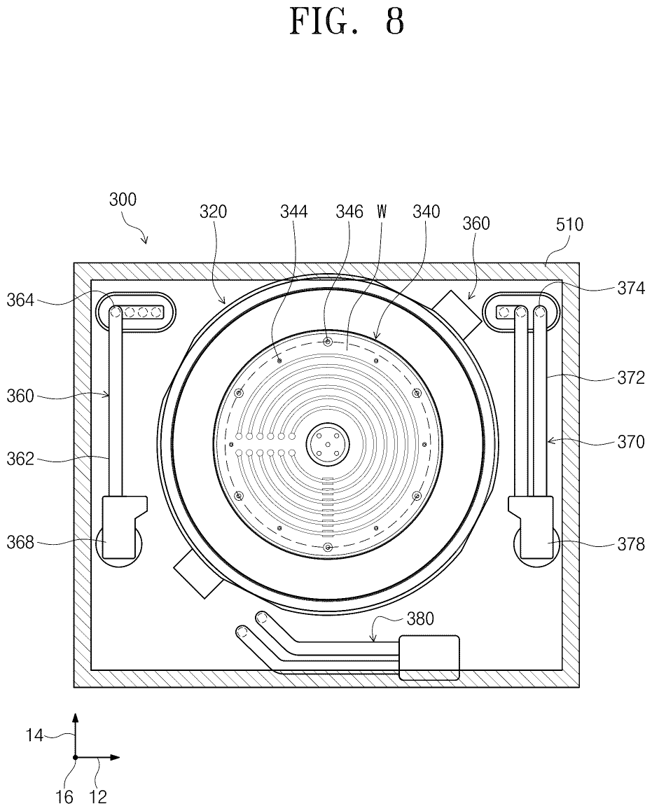

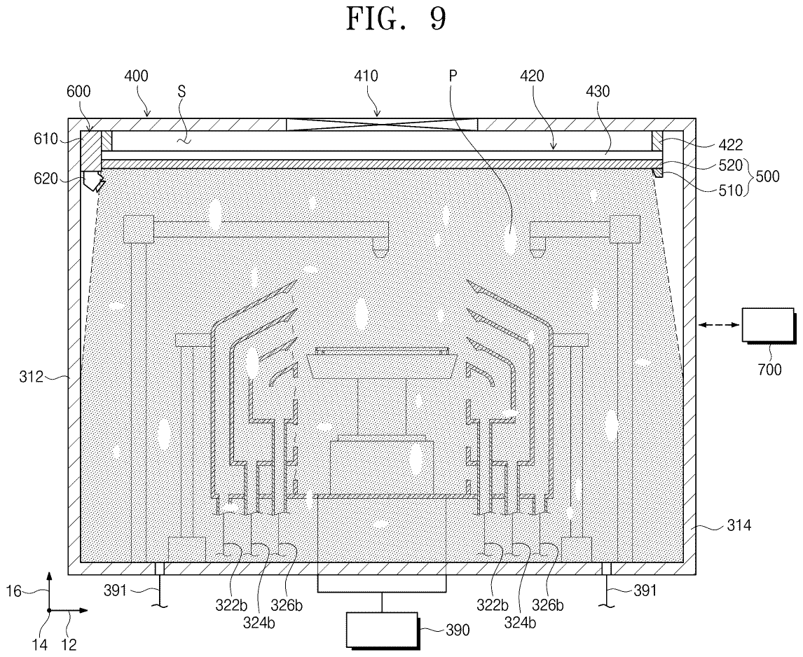

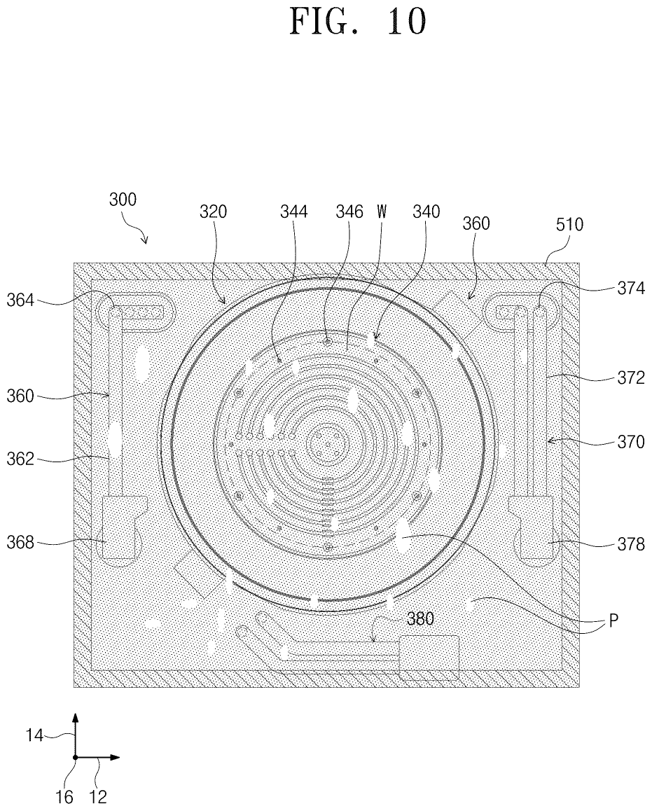

FIGS. 7 to 8 are conceptual diagrams for describing an image of the inner space of the liquid treating chamber when the second light is emitted thereto. FIGS. 9 to 10 are conceptual views for describing an image of the inner space of the liquid treating chamber when the first light is emitted thereto.

Referring to FIGS. 7 to 8, in the case of the image acquired by photographing, by the camera 620, the inner space irradiated with the second light, particles P are not detected. Referring to FIGS. 9 to 10, in contrast, in the case of the image acquired by photographing, by the camera 620, the inner space irradiated with the first light, particles P are detected. That is, when the second light, which is the wavelength band of the visible light, is emitted, scattering between the second light and the particle P of the inner space does not occur or occurs very weakly so that particles P are not detected, but when the first light, which is the wavelength band of the ultraviolet light, is emitted, scattering between the first light and the particle P of the inner space occurs and particles P may be detected.

Referring back to FIG. 6, the control unit 700 inspects the degree of contamination of the inner space based on the image. The control unit 700 inspects the degree of contamination of the inner space by detecting the amount of particles remaining in the inner space from the image. For example, the control unit 700 may compare the image with a pre-stored image to inspect the degree of contamination of the inner space.

The substrate processing apparatus determines whether the degree of contamination of the inner space is greater than a preset value (S532). When the degree of contamination of the inner space is less than the preset value (NO in S532), the substrate processing apparatus determines that the cleaning operation S520 has been performed by satisfying a preset criterion, and processes a subsequent substrate.

When the degree of contamination of the inner space is greater than the preset value (YES of S532), an additional cleaning operation is performed (S533). The additional cleaning operation is an operation of secondarily cleaning the liquid treating chamber 300. The control unit 700 determines that the cleaning operation S520 has not been performed because the cleaning operation S520 satisfies the preset criterion. In this case, the additional cleaning operation S533 is performed in the same manner as the cleaning operation in S520. However, in the additional cleaning operation, the supply amount per unit time of the descending airflow may be a second supply amount, and the exhaust pressure per unit time may be a second exhaust pressure. However, in the additional cleaning operation, the supply amount per unit time of the descending airflow may be a second supply amount, and the exhaust pressure per unit time may be a second exhaust pressure. The second supply amount and the second exhaust pressure are greater than the first supply amount and the first exhaust amount in the cleaning operation S520. Also, the pressure of the inner space in the additional cleaning operation S533 may be the same as the pressure of the inner space in the cleaning operation S520.

In the above-described example, it has been described that the chamber cleaning operation S520 and the additional cleaning operation S533 are performed by supplying the cleaning liquid onto the rotating spin chuck 342. However, unlike this, the chamber cleaning operation S520 and the additional cleaning operation S533 may be performed by directly cleaning, by the operator, the inner wall of the chamber or the components disposed in the chamber.

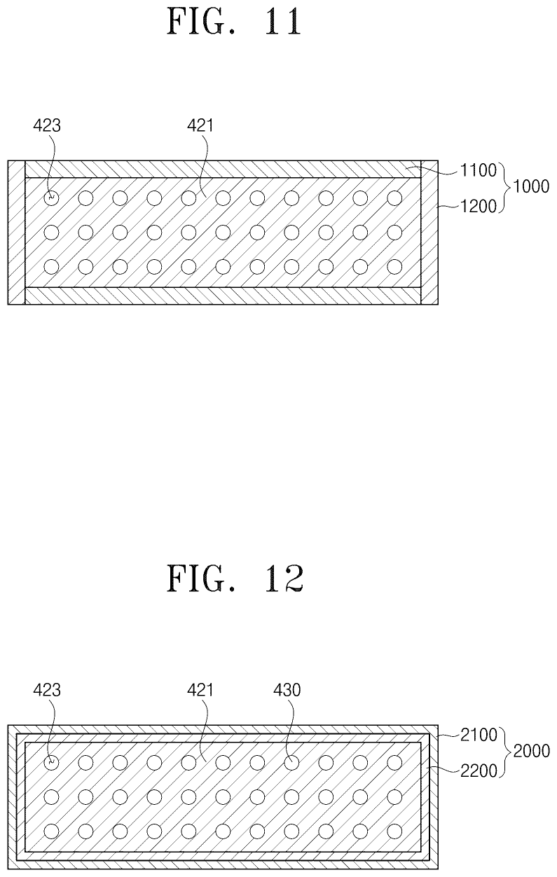

FIG. 11 is a conceptual view for describing the light emitting unit according to the exemplary embodiment of the present invention.

Referring to FIG. 11, the light emitting unit 1000 includes a first light source 1100 and a second light source 1200. The first light source 1100 is a light source for emitting the first light, and the second light source 1200 is a light source for emitting the second light. The first light source 1100 is installed at one side with respect to the center of the lower wall 412, and the second light source 1200 is installed at the other side with respect to the center of the lower wall 412. Unlike this, the first light source 1100 may be installed at the other side with respect to the center of the lower wall 412, and the second light source 1200 may be installed at one side with respect to the center of the lower wall 412.

FIG. 12 is a conceptual view for describing the light emitting unit according to the exemplary embodiment of the present invention.

Referring to FIG. 12, a light emitting unit 2000 includes one light source, and one light source emits the first light and the second light. When viewed from below, the light emitting unit 2000 may be provided in a quadrangular ring shape.

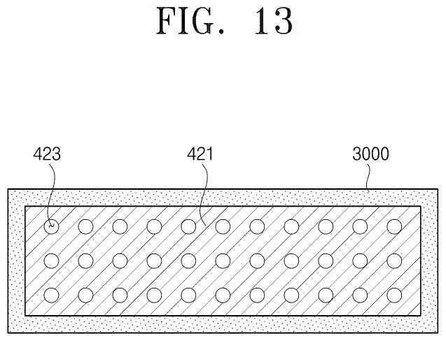

FIG. 13 is a conceptual view for describing the light emitting unit according to the exemplary embodiment of the present invention.

Referring to FIG. 13, a light emitting unit 3000 includes one light source, and one light source irradiates the first light and the second light. When viewed from below, the light emitting unit 3000 may be provided in a quadrangular ring shape.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. A method of processing a substrate, the method comprising:
a substrate processing operation of discharging a liquid to a substrate loaded into an inner space of a liquid treating chamber to liquid-treat the substrate;
after the substrate processing operation, a chamber cleaning operation of unloading the substrate from the inner space of the liquid treating chamber and cleaning the liquid treating chamber; and
an inspection operation of inspecting a degree of contamination of the liquid treating chamber after the chamber cleaning operation,
wherein the inspection operation includes acquiring an image by photographing the inner space with a camera in a state where first light of a wavelength band in an ultraviolet ray region is irradiated to the inner space of the liquid treating chamber, and inspecting the degree of contamination of the liquid treating chamber based on the image.

2. The method of claim 1, wherein in the inspection operation, the degree of contamination of the liquid treating chamber is performed by detecting the amount of particles remaining in the liquid treating chamber from the image.

3. The method claim 2, wherein the degree of contamination of the liquid treating chamber is a degree of contamination of an inner wall of the liquid treating chamber or a degree of contamination of a component provided to the liquid treating chamber.

4. The method claim 1, further comprising:
an additional cleaning operation of secondarily cleaning the liquid treating chamber when it is determined that the degree of contamination is equal to or greater than a preset value in the inspection operation.

5. The method of claim 4, wherein in the chamber cleaning operation, the liquid treating chamber is cleaned with a cleaning liquid in a state where descending airflow is supplied to the inner space at a first supply amount per unit time,
in the additional cleaning operation, the liquid treating chamber is cleaned with the cleaning liquid in a state where descending airflow is supplied to the inner space at a second supply amount per unit time, and
the second supply amount is greater than the first supply amount.

6. The method of claim 5, wherein in the additional cleaning operation, the second supply amount is determined based on the amount of particles detected in the inspection operation.

7. The method of claim 5, wherein an exhaust pressure of the inner space in the additional cleaning operation is greater than an exhaust pressure of the inner space in the chamber cleaning operation, and
a pressure of the inner space in the chamber cleaning operation and a pressure of the inner space in the additional cleaning operation are the same.

8. The method of claim 1, wherein in the substrate processing operation or the chamber cleaning operation, the inner space is photographed by the camera in a state where second light of a different wavelength band from the first light is emitted to the inner space.

9. The method of claim 8, wherein in the substrate processing operation or the chamber cleaning operation, only the second light between the first light and the second light is emitted, and
in the inspection operation, only the first light between the first light and the second light is emitted.

10. The method of claim 8, wherein the second light is light of a wavelength band of a visible light region.

11.-17. (canceled)

18. A method of processing a substrate, the method comprising:
a substrate processing operation of discharging a liquid to a substrate loaded into an inner space of a liquid treating chamber to liquid-treat the substrate;
a chamber cleaning operation of unloading the substrate from the inner space of the liquid treating chamber and cleaning the liquid treating chamber, after the substrate processing operation; and
an inspection operation of inspecting a degree of contamination of the liquid treating chamber, after the chamber cleaning operation,
wherein the inspection operation includes acquiring an image by photographing the inner space with a camera in a state where first light of a wavelength band of an ultraviolet ray region is irradiated to the inner space of the liquid treating chamber, and inspecting a degree of contamination of the liquid treating chamber based on the image,
in the substrate processing operation or the chamber cleaning operation, the inner space is photographed by the camera in a state where second light of a different wavelength band from the first light is emitted to the inner space,
in the substrate processing operation or the chamber cleaning operation, only the second light between the first light and the second light is emitted,
in the inspection operation, only the first light between the first light and the second light is emitted, and
the wavelength band of the second light is a wavelength band of a visible light region.

19. The method of claim 18, further comprising:
an additional cleaning operation of secondarily cleaning the liquid treating chamber when it is determined that the degree of contamination is equal to or greater than a preset value in the inspection operation,
wherein in the chamber cleaning operation, the liquid treating chamber is cleaned with a cleaning liquid in a state where descending airflow is supplied to the inner space at a first supply amount per unit time,
in the additional cleaning operation, the liquid treating chamber is cleaned with the cleaning liquid in a state where descending airflow is supplied to the inner space at a second supply amount per unit time, and
the second supply amount is greater than the first supply amount.

20. The method of claim 19, wherein in the additional cleaning operation, the second supply amount is determined based on the amount of particles detected in the inspection operation,
an exhaust pressure of the inner space is greater than an exhaust pressure of the inner space in the chamber cleaning operation, and
a pressure of the inner space in the chamber cleaning operation and a pressure of the inner space in the additional cleaning operation are the same.
